(19) United States
(12) Patent Application Publication
(10) Pub. No.: US 2026/0247703 A1
(43) Pub. Date: Aug. 20, 2026

(54) SPACER CONFIGURATIONS FOR STACKED SEMICONDUCTOR DEVICES

(71) Applicant: International Business Machines Corporation, Armonk, NY (US)

(72) Inventors: Debarghya Sarkar, Latham, NY (US); Ruilong Xie, Niskayuna, NY (US); Jay William Strane, Wappingers Falls, NY (US); Junli Wang, Slingerlands, NY (US)

(21) Appl. No.: 19/058,618

(22) Filed: Feb. 20, 2025

(51) Int. Cl. H10D 84/85; H01L 23/00; H01L 25/065; H10D 30/00; H10D 30/01; H10D 30/43; H10D 62/10; H10D 64/01; H10D 64/66; H10D 80/30

(52) U.S. Cl. CPC H10D 84/851; H10D 30/014; H10D 30/0191; H10D 30/43; H10D 30/502; H10D 62/102; H10D 62/121; H10D 64/021; H10D 64/675; H10D 84/856; H10D 80/30; H10W 72/01; H10W 72/073; H10W 72/07331; H10W 72/07353; H10W 72/334; H10W 90/00; H10W 90/20; H10W 90/732

(57) ABSTRACT

A semiconductor device includes a first transistor device comprising a plurality of channel layers, one or more first spacers separating the plurality of channel layers, and a second spacer. The second spacer is disposed beneath the plurality of channel layers and has a width greater than that of the one or more first spacers.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for forming spacer configurations for stacked semiconductor devices.

In one embodiment, a semiconductor device includes a first transistor device comprising a plurality of channel layers, one or more first spacers separating the plurality of channel layers, and a second spacer. The second spacer is disposed beneath the plurality of channel layers and has a width greater than that of the one or more first spacers.

In another embodiment, a semiconductor device includes a first device level comprising a first transistor device and a second device level vertically stacked on the first device level. The second device level includes a second transistor device comprising a plurality of channel layers, one or more first spacers separating the plurality of channel layers, and a second spacer. The second spacer is disposed beneath the plurality of channel layers and has a width greater than that of the one or more first spacers.

In yet another embodiment, a method includes forming a first device level, where the first device level includes a plurality of channel layers alternatively stacked with a plurality of first sacrificial layers, a second sacrificial layer disposed above the plurality of channel layers and the plurality of first sacrificial layers, and at least one bonding layer disposed above the second sacrificial layer. The method includes bonding the first device level to a second device level via the at least one bonding layer, removing one or more portions of the second sacrificial layer, and forming a first spacer in the removed one or more portions of the second sacrificial layer. The method further includes removing one or more portions of the plurality of first sacrificial layers; and forming one or more second spacers in the removed portions of the plurality of first sacrificial layers, where each of the one or more second spacers has a width less than that of the first spacer.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating an X cross-section location on which the cross-sectional views of FIGS. 2-4 are based.

FIG. 2 depicts a cross-sectional view of the semiconductor structure corresponding to the line X in FIG. 1 during an intermediate step of a method of fabricating a nanosheet transistor structure, according to an illustrative embodiment.

FIG. 3 depicts a cross-sectional view of the semiconductor structure corresponding to the line X in FIG. 1 following formation of a bottom sacrificial layer for the top device level, according to an embodiment.

FIG. 4 depicts a cross-sectional view of the semiconductor structure corresponding to the line X in FIG. 1 following formation of a bonding layer, according to an embodiment.

FIG. 5 depicts a top view of the semiconductor structure indicating an X cross-section location on which the cross-sectional views of FIGS. 6-13 are based.

FIG. 6 depicts a cross-sectional view of the semiconductor structure corresponding to the line X in FIG. 1 following bonding of the top device level to a bottom device level, according to an embodiment.

FIG. 7 depicts a cross-sectional view of the semiconductor structure corresponding to the line X in FIG. 1 following removal of a wafer layer corresponding to the top device level, according to an embodiment.

FIG. 8 depicts a cross-sectional view of the semiconductor structure corresponding to the line X in FIG. 1 following dummy gate layer formation and nanosheet recessing for the top device level, according to an embodiment.

FIG. 9 depicts a cross-sectional view of the semiconductor structure corresponding to the line X in FIG. 1 following indentation of the bottom sacrificial layer corresponding to the top device level, according to an embodiment.

FIG. 10 depicts a cross-sectional view of the semiconductor structure corresponding to the line X in FIG. 1 following formation of a bottom inner spacer layer for the top device level, according to an embodiment.

FIG. 11 depicts a cross-sectional view of the semiconductor structure corresponding to the line X in FIG. 1 following formation of additional inner spacer layers for the top device level, according to an embodiment.

FIG. 12 depicts a cross-sectional view of the semiconductor structure corresponding to the line X in FIG. 1 following formation of a top source/drain region, according to an embodiment.

FIG. 13 depicts a cross-sectional view of the semiconductor structure corresponding to the line X in FIG. 1 following gate formation for the top device level, according to an embodiment.

### DETAILED DESCRIPTION

Illustrative embodiments may be described herein in the context of illustrative methods for forming spacer configurations for stacked semiconductor devices, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

A FET is a three-terminal device having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the area of FETs. One technique is through the use of fin-shaped channels in FinFET devices. Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures the gate can more effectively control the channel, as the gate extends over more than one side or surface of the channel. In FinFET arrangements, the gate encloses three surfaces of the three-dimensional channel, rather than being disposed over just the top surface of a traditional planar channel.

Another useful technique for reducing the size of FETs is through the use of stacked nanosheet channels formed over a semiconductor substrate. Stacked nanosheets may be two-dimensional nanostructures, such as sheets having a thickness range on the order of 1 to 100 nanometers (nm). Nanosheets and nanowires are viable options for scaling to 7 nm node and beyond. A general process flow for formation of a nanosheet stack involves removing sacrificial layers, which may be formed of silicon germanium (SiGe), between sheets of channel material, which may be formed of silicon (Si).

For continued scaling and area improvement, stacked transistor structures may be used. A stacked transistor structure may include multiple transistors stacked over one another vertically. For example, stacked transistor structures may utilize sequential integration fabrication processes. Sequential integration includes forming “bottom” transistors of a stacked transistor structure, followed by wafer bonding and formation of “top” transistors of the stacked transistor structure. The bottom and top transistors of the stacked transistor structure may also be referred to as being different “levels” of the stacked transistor structure (e.g., where the bottom transistors are a bottom device level of the stacked transistor structure and the top transistors are a top device level of the stacked transistor structure). Sequential integration fabrication processes provide various advantages relative to monolithic fabrication processes. For example, sequential integration allows for: an increased effective width (Weff) with the same device footprint; increasing the number of channels (e.g., nanosheet channels); and further critical dimension (CD) scaling. Since the top and bottom device levels are integrated separately, sequential integration allows for unique transistor architectures (e.g., shifted, staggered, etc.), split gate schemes, multiple threshold voltage (multi-Vt) replacement metal gate (RMG) learning from nanosheets, channel engineering for the top and bottom device levels (e.g., mobility), and reduced process complexity.

Stacked transistor structures may use different transistor architectures, such as a “stepped” architecture (e.g., where nanosheet channels for the top transistors of a stacked transistor structure are narrower than nanosheet channels for the bottom transistors of the stacked transistor structure) and an “aligned” architecture (e.g., where nanosheet channels for the top and bottom transistors of a stacked transistor structure have the same size and are aligned with one another). Wafer bonding approaches used in sequential integration fabrication processes further allow for a “shifted” architecture (e.g., where the active regions or nanosheet channels for the top and bottom transistors of the stacked transistor structure are offset from one another) and a “staggered” architecture (e.g., where cell or device boundaries for the top and bottom transistors of the stacked transistor structure are offset from one another). Both the shifted and staggered architectures provide for lower aspect ratio (AR) for middle-of-line (MOL) contact formation, and also provide a Weff benefit with respect to the aligned active regions.

Typically, one or more bonding layers are used to bond the top device level and the bottom device level in a stacked transistor structure. A pre-clean process (e.g., a hydrofluoric acid-based pre-clean process) is generally performed prior to forming the top source/drain region, which can lead to imperfections (e.g., gouges and/or undercuts) in the bonding layer. When the top source/drain region is formed, it can extend into at least portions of the imperfections of the bonding layer. Formation of gate structures for the top device level can result in further imperfections in the bonding layer. The imperfections can lead to various issues such as increased capacitance and/or shorts between the gate structures and the source/drain region.

Embodiments described herein provide stacked transistor structures with reduced bonding layer imperfections. By introducing a bottom inner spacer beneath the top device level's nanosheet channels, it effectively prevents shorts between gate structures and source/drain regions, ensuring robust fabrication without compromising device performance.

Detailed embodiments of stacked transistor structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not intended to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc., may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present disclosure.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

The term “sacrificial” as used herein generally refers to a placeholder feature that will be removed to define a new or different feature.

The term “substrate” as used herein may refer to material that provides a support structure to features in or on top of the substrate material. As used herein, there may be more than one substrate present in an embodiment shown. Also, since embodiments below are generally shown in cross-section, it should be understood that a substrate for a layer with patterned features may not be visible in the view so as to highlight the features for the layer.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

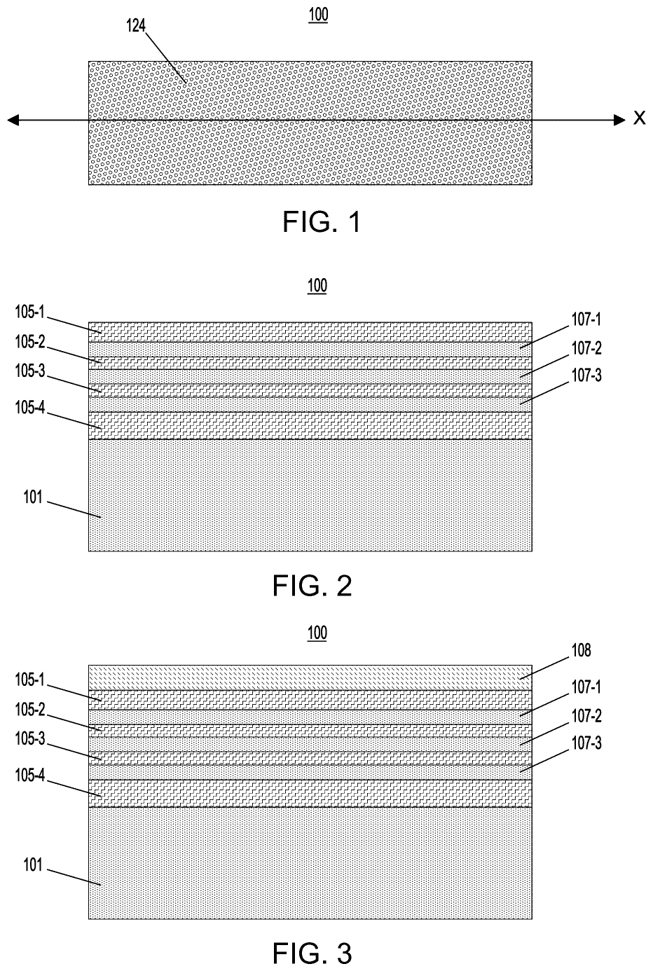

An example of a method for forming a semiconductor device is now described with reference to FIGS. 1-13.

FIG. 1 depicts a top view of a semiconductor structure 100 indicating an X cross-section location on which the cross-sectional views of FIGS. 2-4 are based. The semiconductor structure 100 includes an active region 124 for a top device level of a stacked transistor structure. In some embodiments, the active region 124 may correspond to either an n-type transistor or a p-type transistor, and an active region for a bottom device level (e.g., active region 125 shown in FIG. 5) may correspond to the other one of the n-type transistor and the p-type transistor.

Referring also to FIG. 2, the semiconductor structure 100 includes a carrier wafer 101 and a nanosheet stack comprising alternating sacrificial layers 105-1, 105-2, 105-3, and 105-4 (collectively “sacrificial layers 105”) and channel layers 107-1, 107-2, and 107-3 (collectively “channel layers 107”). The carrier wafer 101 may be formed of silicon (Si) or another suitable material. The semiconductor structure shown in FIG. 2 may be formed by depositing the nanosheet stack (e.g., the sacrificial layers 105 and the channel layers 107) over the carrier wafer 101.

In some embodiments, the sacrificial layers 105 are formed of SiGe with a germanium (Ge) concentration in the range of 20-40%. The channel layers 107 provide channels for transistors (e.g., nanosheet transistors) in the top device level of the semiconductor structure 100. In some embodiments, the channel layers 107 may be formed of Si or another suitable material.

FIG. 3 depicts a cross-sectional view of the semiconductor structure 100 corresponding to the line X in FIG. 1 following formation of a bottom sacrificial layer 108 for the top device level. The bottom sacrificial layer 108 may be formed on top of the sacrificial layer 105-1. In some embodiments, the bottom sacrificial layer 108 may comprise SiGe having a different Ge concentration than the sacrificial layers 105. As a non-limiting example, the bottom sacrificial layer 108 can have a Ge concentration of approximately 55% and the sacrificial layers 105 can have a Ge concentration of approximately 25%.

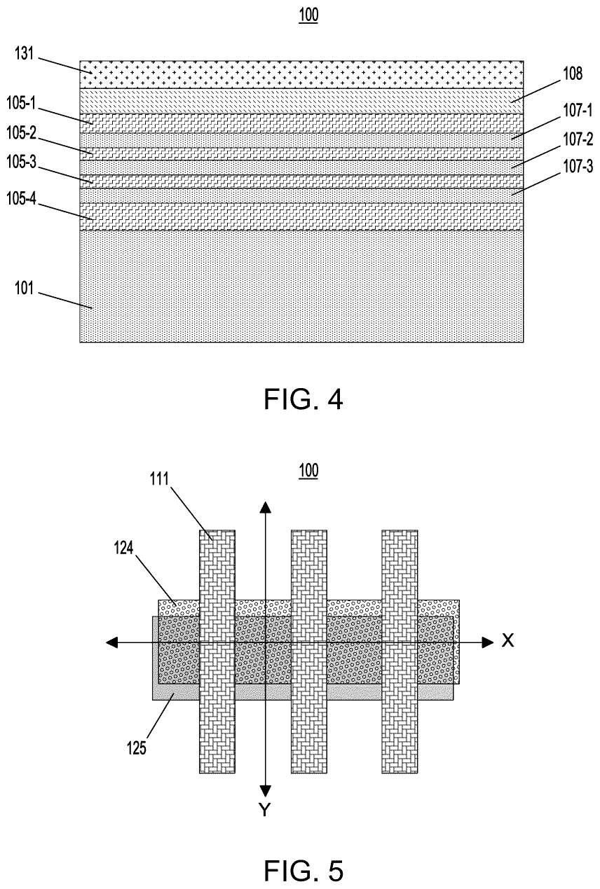

FIG. 4 depicts a cross-sectional view of the semiconductor structure 100 corresponding to the line X in FIG. 1 following formation of a bonding layer 131. The bonding layer 131 can be formed by depositing a dielectric bonding oxide material such as, for example, silicon dioxide, tetraethylorthosilicate (TEOS), or fluorinated tetraethylorthosilicate (FTEOS) using a deposition process (e.g., CVD or PECVD).

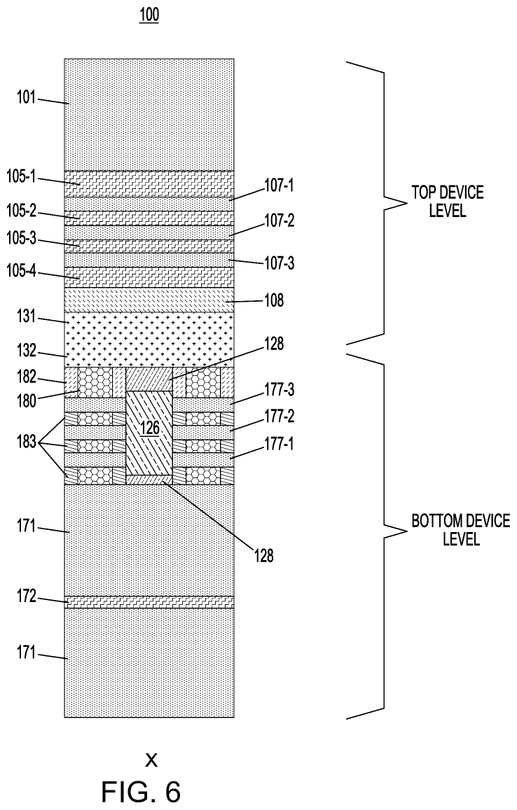

FIG. 5 depicts a top view of the semiconductor structure 100 indicating an X cross-section location on which the cross-sectional views of FIGS. 6-13 are based. FIG. 5 shows an active region 125 for a bottom device level and dummy gate portions 111. The dummy gate portions 111 correspond to areas of the semiconductor structure 100 where gate structures 140 and 180 are formed. The active region 125 corresponds to areas of the semiconductor structure 100 where a bottom source/drain region 126 is formed, and the active region 124 corresponds to areas where a top source/drain region 127 is formed.

Referring also to FIG. 6, this figure shows a cross-sectional view of the semiconductor structure corresponding to the line X in FIG. 5 following bonding of the top device level to the bottom device level. In some embodiments, the bottom device level can be fabricated prior to the top device level being bonded to the bottom device level. In the example shown in FIG. 6, the bottom device level includes a bonding layer 132, a substrate 171, an etch stop layer 172, channel layers 177-1, 177-2, and 177-3 (collectively “channel layers 177”), gate structures 180, gate spacers 182, inner spacers 183, the bottom source/drain region 126, and an interlayer dielectric (ILD) layer 128.

The substrate 171 may be formed of any suitable semiconductor material, including various silicon-containing materials such as silicon (Si), silicon germanium (SiGe), silicon germanium carbide (SiGeC), silicon carbide (SiC) and multi-layers thereof. Although silicon is the predominantly used semiconductor material in wafer fabrication, alternative semiconductor materials can be employed as additional layers, such as, but not limited to, germanium (Ge), gallium arsenide (GaAs), gallium nitride (GaN), SiGe, cadmium telluride (CdTe), and zinc selenide (ZnSe)

The etch stop layer 172 is formed in the substrate 171. The etch stop layer 172 may comprise a buried oxide (BOX) layer or silicon germanium (SiGe), or another suitable material such as a III-V semiconductor epitaxial layer.

To form the bottom device level shown in FIG. 6, nanosheets are formed on the substrate 171, where the nanosheets include the channel layers 177 and sacrificial layers (not shown in FIG. 6). The channel layers 177 may be formed of Si or another suitable material (e.g., a material similar to that used for the substrate 171). The sacrificial layers and the channel layers 177 can be epitaxially grown in an alternating and stacked configuration on the substrate 171.

The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

Due to, for example, germanium in the sacrificial layers 105, lateral etching of the sacrificial layers can be performed selective to the channel layers 177, such that the side portions of the sacrificial layers can be removed to create vacant areas, which are filled in by the inner spacers 183. The material of the inner spacers 183 can comprise, but is not necessarily limited to, a nitride such as SiN, SiON, SiCN, BN, SiBN, SiBCN, or SiOCN. The inner spacers 183 can be formed by any suitable technique such as deposition followed by directional etching.

The gate spacers 182 are positioned on side portions of the gate structures 180 above the channel layer 177-3. The material of the gate spacers 182 can comprise for example, one or more dielectrics, including, but not necessarily limited to, SiN, SiON, SiOC, SiCN, BN, SiBN, SiBCN, SiOCN, SiOₓ, or combinations thereof.

The bottom source/drain region 126 is formed between the stacked structure of the sacrificial layers and the bottom channel layers 177. In the case of n-type FETs (nFETs), the bottom source/drain region 126 can comprise silicon doped with n-type dopants including, for example, phosphorus (P), arsenic (As), and antimony (Sb). In the case of p-type FETS (pFETs), the bottom source/drain region 126 can comprise silicon doped with p-type dopants such as boron (B), boron fluoride (BF₂), gallium (Ga), indium (In), and thallium (Tl).

It is noted that the sacrificial layers have been replaced by the gate structures 180 in FIG. 6, and the interlayer dielectric (ILD) layer 128 is formed to fill in portions on and around the bottom source/drain region 126. The ILD layer 128 can be deposited using deposition techniques such as, for example, CVD, PECVD, RFCVD, PVD, ALD, MBD, PLD, and/or LSMCD. The ILD layer 128 may comprise, for example, SiOx, SiOC, SiOCN, or some other dielectric.

The bonding layer 132 is formed above the gate structures 180, the ILD layer 128, and the gate spacers 182. The bonding layer 132 can be formed using similar techniques and materials as the bonding layer 131, for example. The top device level is bonded to the bottom device level via bonding layers 131 and 132 using, for example, an oxide-to-oxide bonding process.

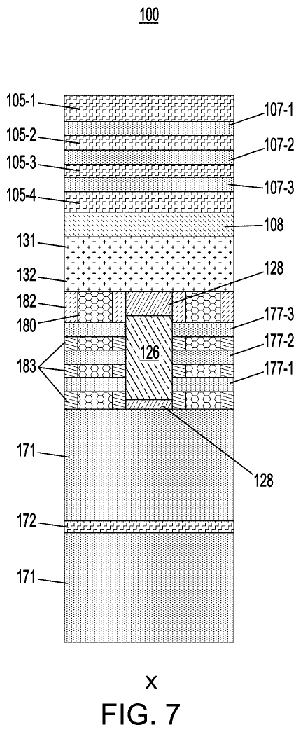

FIG. 7 depicts a cross-sectional view of the semiconductor structure 100 corresponding to the line X in FIG. 1 following removal of the carrier wafer 101. The carrier wafer 101 can be removed using any suitable planarization process (e.g., CMP). Following removal of the carrier wafer 101, the nanosheet stack of the sacrificial layers 105, the channel layers 107, and the bottom sacrificial layer 108 remain on the bonding layer 131.

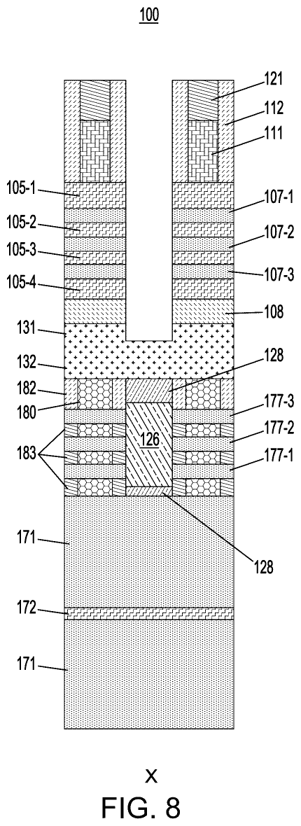

FIG. 8 depicts a cross-sectional view of the semiconductor structure corresponding to the line X in FIG. 1 following recessing of the nanosheet stack of the sacrificial layers 105, the channel layers 107, and the bottom sacrificial layer 108, and formation of dummy gate portions 111. Portions of the stacked structure of the sacrificial layers 105, the channel layers 107 are removed. In this example, the bonding layer 131 is recessed to a level below the bottom sacrificial layer 108.

The dummy gate portions 111 are formed on the uppermost channel layer 107-3 and around the stacked structure of the sacrificial layers 105 and the channel layers 107. The dummy gate portions 111 include, but are not necessarily limited to, an amorphous silicon (a-Si) layer. The dummy gate portions 111 are deposited using deposition techniques such as CVD, PECVD, RFCVD, PVD, ALD, MBD, PLD, LSMCD, sputtering and/or plating, followed by a planarization process, such as CMP, and lithography and etching steps to remove excess dummy gate material and pattern the deposited layer.

A hardmask (HM) layer 121 is formed on the dummy gate portions 111 using a suitable deposition technique (e.g., PVD, ALD, CVD, etc.), followed by a planarization process (e.g., CMP). The HM layer 121 can be formed of a suitable masking material such as a nitride, amorphous silicon, or another suitable material.

The gate spacers 112 are formed on sides of the HM layer 121 and dummy gate portions 111 by one or more of the deposition techniques noted in connection with the deposition of the dummy gate material. The spacer material can comprise, for example, one or more dielectrics, such as but not limited to, SiN, SiON, SiOC, SiCN, BN, SiBN, SiBCN, SiOCN, SiOₓ, and combinations thereof. According to an embodiment, the HM layer 121 and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

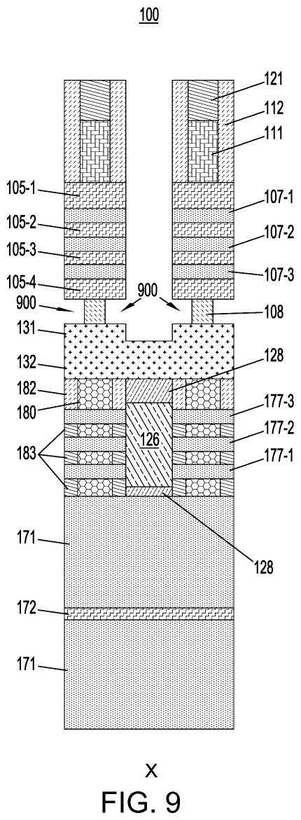

FIG. 9 depicts a cross-sectional view of the semiconductor structure 100 corresponding to the line X in FIG. 1 following an indentation process to remove portions of the bottom sacrificial layer 108. The indentation process can remove portions of the bottom sacrificial layer 108 to form indentations 900. The portion of the bottom sacrificial layer 108 can be selectively removed due to the germanium concentration of the bottom sacrificial layer 108, the portions can be removed selective to the channel layers 107 and the sacrificial layers 105, for example.

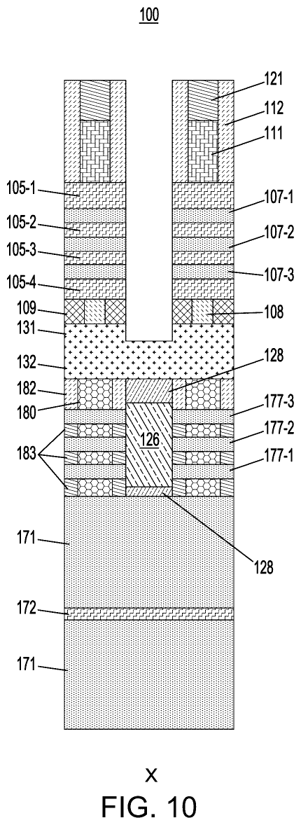

FIG. 10 depicts a cross-sectional view of the semiconductor structure 100 corresponding to the line X in FIG. 1 following formation of bottom inner spacers 109 for the top device level. The bottom inner spacers 109 are formed by filling in the indentations 900 with a dielectric material. The material of the bottom inner spacers 109 can comprise, but is not necessarily limited to, a nitride such as SiN, SiON, SiCN, BN, SiBN, SiBCN, or SiOCN. The bottom inner spacers 109 can be formed by any suitable technique such as deposition followed by directional etching.

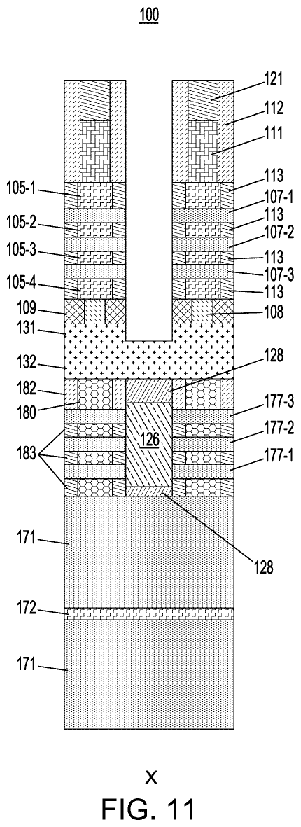

FIG. 11 depicts a cross-sectional view of the semiconductor structure 100 corresponding to the line X in FIG. 1 following formation of additional inner spacers 113 for the top device level. The additional inner spacers 113 can be formed using similar techniques and materials as the inner spacers 183, for example. According to some embodiments, the material of the bottom inner spacers 109 can have a high etch-selectivity with respect to the bonding layer 131. The additional inner spacers 113 can be formed of a different material than the bottom inner spacers 109 to prevent or limit any adverse effects to the bottom inner spacers 109 during the removal of the side portions of the sacrificial layers 105 when forming the additional inner spacers 113. In some embodiments, the width of the bottom inner spacers 109 can be greater than the width of the additional inner spacers 113, as shown in FIG. 11.

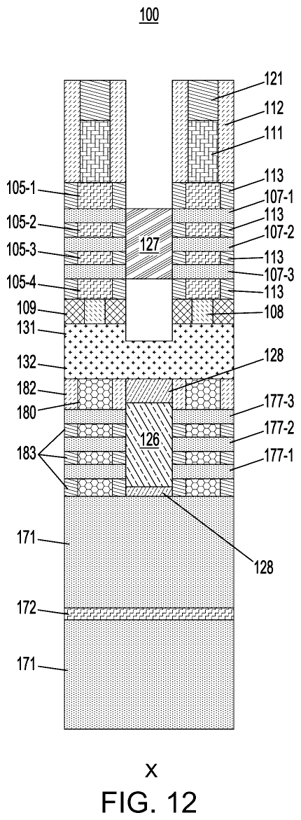

FIG. 12 depicts a cross-sectional view of the semiconductor structure 100 corresponding to the line X in FIG. 1 following formation of a top source/drain region 127. The top source/drain region 127 can be formed using similar techniques and materials as the bottom source/drain region 126.

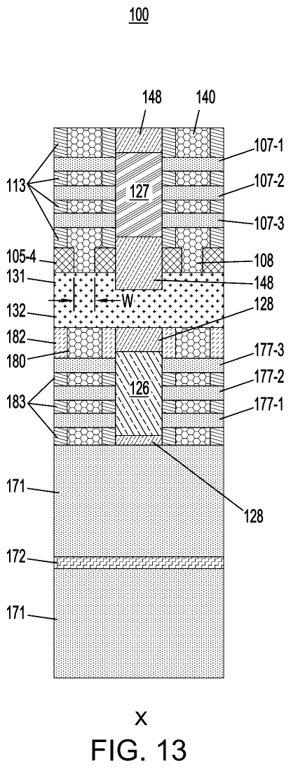

FIG. 13 depicts a cross-sectional view of the semiconductor structure 100 corresponding to the line X in FIG. 1 following a replacement metal gate (RMG) process. The RMG process includes depositing an ILD layer 148 to fill in portions on and around the top source/drain region 127. The ILD layer 148 is deposited using deposition techniques such as, for example, CVD, PECVD, RFCVD, PVD, ALD, MBD, PLD, and/or LSMCD, followed by a planarization process, such as, a POC process, to remove excess portions of the ILD layer 148 deposited on top of the HM layer 121 and gate spacers 112, and to remove the HM layer 121 and portions of the gate spacers 112 to expose the dummy gate portions 111. The ILD layer 148 may comprise, for example, SiOx, SiOC, SiOCN or some other dielectric.

The dummy gate portions 111, the sacrificial layers 105, and the bottom sacrificial layer 108 are selectively removed to create vacant areas, in which the gate structures 140 will be formed. For example, the dummy gate portions 111 can be selectively removed using hot ammonia to remove a-Si, and the sacrificial layers 105 and the bottom sacrificial layer 108 can be selectively removed with respect to the channel layers 107 using, for example, a dry HCl etch.

The gate structures 140, including, for example, gate and dielectric portions are formed in the vacant areas left by the removal of the dummy gate portions 111, the additional sacrificial layers 105, and the bottom sacrificial layer 108. In illustrative embodiments, each of the gate structures 140 and 180 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate structures 140 and 180 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals such as tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

In at least one embodiment, the width, W, between the bottom inner spacers 109 corresponding to a given one of the gate structures 140 can vary based on a length of the given one of the gate structures 140, where W is greater than or equal to zero. For example, the bottom inner spacers 109 may be a discontinuous layer where W>0, or a continuous layer where W=0, depending on the application. For example, W=0 can provide the best isolation between the given one of the gate structures 140 and the top source/drain region 127. Notably, the presence of the bottom inner spacers 109 can mitigate or eliminate undercuts in the bonding layer 131 when performing a pre-clean process prior to forming the top source/drain region 127 and/or when performing the RMG process.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a semiconductor device includes a first transistor device comprising a plurality of channel layers, one or more first spacers separating the plurality of channel layers, and a second spacer. The second spacer is disposed beneath the plurality of channel layers and has a width greater than that of the one or more first spacers.

The inclusion of the second spacer in the semiconductor device of the present embodiment can effectively reduce imperfections caused by pre-clean processes or wet steps during fabrication, thereby ensuring protection against shorts (e.g., between gate structures and source/drain regions) while maintaining low capacitance.

In embodiments, the width of the second spacer may be based at least in part on a length of a gate structure contacting the plurality of channel layers of the first transistor device.

In embodiments, the semiconductor device may further include a third spacer adjacent to the second spacer, wherein the second spacer and third spacer correspond to a same gate structure, and wherein a width of a gap between the second spacer and the third spacer is greater than or equal to zero.

In embodiments, the semiconductor device may further include at least one bonding layer positioned beneath the second spacer, where the second spacer includes a material having a high etch-selectivity relative to the at least one bonding layer.

In embodiments, the second spacer may be disposed between the at least one bonding layer and the one or more first spacers.

In embodiments, the semiconductor device may further include a first source/drain region disposed adjacent to the plurality of channel layers, and an interlayer dielectric layer surrounding at least a portion of the first source/drain region.

In embodiments, the second spacer may include a material having a high etch-selectivity relative to the interlayer dielectric layer. Such embodiments can ensure there is minimal impact to the second spacer during fabrication steps (e.g., wet or plasma etching) involving the interlayer dielectric layer.

In embodiments, the semiconductor device may further include a second source/drain region corresponding to a second transistor device vertically stacked beneath the first transistor device.

In another embodiment, a semiconductor device includes a first device level comprising a first transistor device and a second device level vertically stacked on the first device level. The second device level includes a second transistor device comprising a plurality of channel layers, one or more first spacers separating the plurality of channel layers, and a second spacer. The second spacer is disposed beneath the plurality of channel layers and has a width greater than that of the one or more first spacers.

The inclusion of the second spacer in the semiconductor device of the present embodiment can effectively reduce imperfections caused by pre-clean processes or wet steps during fabrication, thereby ensuring protection against shorts (e.g., between gate structures and source/drain regions) while maintaining low capacitance.

In embodiments, the width of the second spacer may be based at least in part on a length of a gate structure contacting the plurality of channel layers of the second device level.

In embodiments, the semiconductor device may further include a third spacer adjacent to the second spacer, where the second spacer and third spacer correspond to a same gate structure, and where a width of a gap between the second spacer and the third spacer is greater than or equal to zero.

In embodiments, the semiconductor device may further include a first source/drain region, corresponding to the second transistor device, disposed adjacent to the plurality of channel layers, and an interlayer dielectric layer surrounding at least a portion of the first source/drain region.

In embodiments, the second spacer may include a material having a high etch-selectivity relative to the interlayer dielectric layer.

In embodiments, the semiconductor device may further include a second source/drain region corresponding to the first transistor device.

In embodiments, the semiconductor device may further include one or more bonding layers that bond the first device level to the second device level.

In embodiments, the second spacer may include a material having a high etch-selectivity relative to the one or more bonding layers.

In embodiments, the second spacer may include one or more of silicon nitride, silicon oxycarbide, silicon carbide, silicon borocarbonitride, silicon carbonitride, aluminum nitride, and hafnium oxide.

In yet another embodiment, a method includes forming a first device level, where the first device level includes a plurality of channel layers alternatively stacked with a plurality of first sacrificial layers, a second sacrificial layer disposed above the plurality of channel layers and the plurality of first sacrificial layers, and at least one bonding layer disposed above the second sacrificial layer. The method includes bonding the first device level to a second device level via the at least one bonding layer, removing one or more portions of the second sacrificial layer, and forming a first spacer in the removed one or more portions of the second sacrificial layer. The method further includes removing one or more portions of the plurality of first sacrificial layers and forming one or more second spacers in the removed portions of the plurality of first sacrificial layers, where each of the one or more second spacers has a width less than that of the first spacer.

The method of the present embodiment advantageously forms the first spacer in the first device level, which can effectively reduce imperfections in the at least one bonding layer (e.g., caused by pre-clean processes or wet steps during fabrication), thereby ensuring protection against shorts (e.g., between gate structures and source/drain regions) while maintaining low capacitance.

In embodiments, the plurality of first sacrificial layers may include silicon germanium having a first concentration of germanium, and the second sacrificial layer may include silicon germanium having a second concentration of germanium that is different than the first concentration of germanium.

In embodiments, the width of the first spacer may be based at least in part on a length of a gate structure corresponding to the first device level.

Conventional techniques for designing and fabricating semiconductor devices typically involve the use of bonded wafer integration for stacked semiconductors structures, which can lead to significant challenges during fabrication due to imperfections in the bonding layer caused by pre-clean processes or wet steps (e.g., during RMG formation and/or source/drain formation). Embodiments described herein can effectively reduce or prevent such imperfections by forming a bottom spacer to protect the bonding layer during pre-clean processes and wet steps. Such embodiments can advantageously reduce the risk of shorts between source/drain regions and gate structures and maintain low capacitance while ensuring robust fabrication without compromising device performance or reliability.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a first transistor device comprising a plurality of channel layers;
one or more first spacers separating the plurality of channel layers; and
a second spacer, disposed beneath the plurality of channel layers, having a width greater than that of the one or more first spacers.

2. The semiconductor device of claim 1, wherein the width of the second spacer is based at least in part on a length of a gate structure contacting the plurality of channel layers of the first transistor device.

3. The semiconductor device of claim 1, further comprising a third spacer adjacent to the second spacer, wherein the second spacer and third spacer correspond to a same gate structure, and wherein a width of a gap between the second spacer and the third spacer is greater than or equal to zero.

4. The semiconductor device of claim 1, further comprising:
at least one bonding layer positioned beneath the second spacer, wherein the second spacer comprises a material having a high etch-selectivity relative to the at least one bonding layer.

5. The semiconductor device of claim 4, wherein the second spacer is disposed between the at least one bonding layer and the one or more first spacers.

6. The semiconductor device of claim 1, further comprising:
a first source/drain region disposed adjacent to the plurality of channel layers; and
an interlayer dielectric layer surrounding at least a portion of the first source/drain region.

7. The semiconductor device of claim 6, wherein the second spacer comprises a material having a high etch-selectivity relative to the interlayer dielectric layer.

8. The semiconductor device of claim 1, further comprising:
a second source/drain region corresponding to a second transistor device vertically stacked beneath the first transistor device.

9. A semiconductor device comprising:
a first device level comprising a first transistor device; and
a second device level vertically stacked on the first device level, wherein the second device level comprises:
a second transistor device comprising a plurality of channel layers;
one or more first spacers separating the plurality of channel layers; and
a second spacer, disposed beneath the plurality of channel layers, having a width greater than that of the one or more first spacers.

10. The semiconductor device of claim 9, wherein the width of the second spacer is based at least in part on a length of a gate structure contacting the plurality of channel layers of the second device level.

11. The semiconductor device of claim 10, further comprising:
a third spacer adjacent to the second spacer, wherein the second spacer and third spacer correspond to a same gate structure, and wherein a width of a gap between the second spacer and the third spacer is greater than or equal to zero.

12. The semiconductor device of claim 9, further comprising:
a first source/drain region, corresponding to the second transistor device, disposed adjacent to the plurality of channel layers; and
an interlayer dielectric layer surrounding at least a portion of the first source/drain region.

13. The semiconductor device of claim 12, wherein the second spacer comprises a material having a high etch-selectivity relative to the interlayer dielectric layer.

14. The semiconductor device of claim 12, further comprising:
a second source/drain region corresponding to the first transistor device.

15. The semiconductor device of claim 9, further comprising:
one or more bonding layers that bond the first device level to the second device level.

16. The semiconductor device of claim 15, wherein the second spacer comprises a material having a high etch-selectivity relative to the one or more bonding layers.

17. The semiconductor device of claim 9, wherein the second spacer comprises one or more of:
silicon nitride;
silicon oxycarbide; silicon carbide;
silicon borocarbonitride;
silicon carbonitride;
aluminum nitride; and
hafnium oxide.

18. A method comprising:
forming a first device level, wherein the first device level comprises a plurality of channel layers alternatively stacked with a plurality of first sacrificial layers, a second sacrificial layer disposed above the plurality of channel layers and the plurality of first sacrificial layers, and at least one bonding layer disposed above the second sacrificial layer;
bonding the first device level to a second device level via the at least one bonding layer;
removing one or more portions of the second sacrificial layer;
forming a first spacer in the removed one or more portions of the second sacrificial layer;
removing one or more portions of the plurality of first sacrificial layers; and
forming one or more second spacers in the removed portions of the plurality of first sacrificial layers, wherein each of the one or more second spacers has a width less than that of the first spacer.

19. The method of claim 18, wherein:
the plurality of first sacrificial layers comprises silicon germanium having a first concentration of germanium; and
the second sacrificial layer comprises silicon germanium having a second concentration of germanium that is different than the first concentration of germanium.

20. The method of claim 18, wherein the width of the first spacer is based at least in part on a length of a gate structure corresponding to the first device level.
